(19) United States
(12) Patent Application Publication
(10) Pub. No.: US 2026/0254455 A1
(43) Pub. Date: Aug. 27, 2026

(54) CHIP WITH DIFFERENT TYPES OF RESONATORS AND RELATED TIMING PRODUCTS

(71) Applicant: Skyworks Solutions, Inc., Irvine, CA (US)

(72) Inventor: Srisai Rao Seethamraju, Nashua, NH (US)

(21) Appl. No.: 19/551,364

(22) Filed: Feb. 26, 2026

Related U.S. Application Data
(60) Provisional application No. 63/764,417, filed on Feb. 27, 2025.
(60) Provisional application No. 63/764,415, filed on Feb. 27, 2025.

(51) Int. Cl. H03L 7/07; H03H 9/02; H03H 9/205; H03L 7/099; H03H 9/15

(52) U.S. Cl. CPC H03L 7/07; H03H 9/02448; H03H 9/205; H03L 7/099; H03H 2009/155

(57) ABSTRACT

Aspects of this disclosure relate to a chip that includes two types of resonators with different properties. For example, the chip can include a piezoelectric microelectromechanical systems (MEMS) resonator and an electrostatic MEMS resonator. One type of resonator can provide lower phase noise than the other type of resonator, and the other type of resonator can have less variation over temperature. A phase-locked loop can receive reference signals from the two types of resonators. Related MEMS resonator chips, timing products, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/764,415, filed Feb. 27, 2025 and titled “CHIP WITH DIFFERENT TYPES OF MICROELECTROMECHANICAL SYSTEMS RESONATORS,” and claims the benefit of priority of U.S. Provisional Application No. 63/764,417, filed Feb. 27, 2025 and titled “PHASE-LOCKED LOOP ARCHITECTURE WITH DIFFERENT TYPES OF MICROELECTROMECHANICAL SYSTEMS RESONATORS,” the disclosures of each of which are hereby incorporated by reference in their entireties and for all purposes.

### BACKGROUND

### Technical Field

The disclosed technology relates to microelectromechanical systems resonators and related timing products.

### Description of Related Technology

With the data rates used in communication systems, clock sources with low jitter can be desired. Clock sources can utilize phase-locked loops (PLLs) to provide clock signals for communication systems. A clock source can include a PLL that receives a reference clock signal from an oscillator. There are technical challenges associated with generating a clock signal with a PLL and meeting certain performance specifications. Improved clock generators are desired for meeting performance specifications in certain applications.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a microelectromechanical systems (MEMS) resonator chip with different types of MEMS resonators. The MEMS resonator chip can include a substrate, a piezoelectric MEMS resonator on the substrate, and an electrostatic MEMS resonator on the substrate.

The piezoelectric MEMS resonator can have a higher resonant frequency than the electrostatic MEMS resonator. The resonant frequency of the piezoelectric MEMS resonator can be at least 10 times a resonant frequency of the electrostatic MEMS resonator.

The electrostatic MEMS resonator can have a temperature stability that is at least 10 times better than a temperature stability of the piezoelectric MEMS resonator. The electrostatic MEMS resonator can have a temperature stability that is at least 50 times better than a temperature stability of the piezoelectric MEMS resonator. The electrostatic MEMS resonator can have a temperature stability that is in a range from 10 to 50 times better than a temperature stability of the piezoelectric MEMS resonator.

The electrostatic MEMS resonator can be a Lamé mode resonator. The electrostatic MEMS resonator can be a distributed Lamé mode resonator.

The piezoelectric MEMS resonator can include an aluminum nitride piezoelectric layer. The aluminum nitride piezoelectric layer can be doped with scandium.

The substrate can have a mono-crystalline structure. The substrate can be a silicon substrate. The substrate can be a silicon carbide substrate. The substrate can be a 4H SiC substrate. The substrate can be a semiconductor-on-insulator substrate. The substrate can be a silicon-on-insulator substrate.

Another aspect of this disclosure is a timing product that can include a MEMS resonator chip in accordance with any suitable principles and advantages disclosed herein and a nested phase-locked loop. The nested phase-locked loop includes a first phase-locked loop and a second phase-locked loop. The first phase-locked loop is configured as a digitally controlled oscillator of the second phase-locked loop. The first phase-locked loop is configured to receive a first reference signal that is generated using a piezoelectric MEMS resonator. The second phase-locked loop is configured to receive a second reference signal that is generated using an electrostatic MEMS resonator.

The first phase-locked loop and the second phase-locked loop can be fractional-N phase-locked loops.

The nested phase-locked loop can include a third phase-locked loop.

The timing product can further include a memory and a packaging structure. The nested phase-locked loop can be included on an application specific integrated circuit, and the packaging structure can enclose the application specific integrated circuit and the memory and the MEMS resonator chip.

Another aspect of this disclosure is a method of manufacturing a MEMS resonator chip. The method includes forming a piezoelectric MEMS resonator and an electrostatic MEMS resonator on a common semiconductor substrate.

The MEMS resonator chip formed by the method can be implemented in accordance with any suitable principles and advantages disclosed herein.

Another aspect of this disclosure is a timing product that includes a piezoelectric microelectromechanical systems (MEMS) resonator, an electrostatic MEMS resonator, and a phase-locked loop. The phase-locked loop is configured to receive a first reference signal that is generated using the piezoelectric MEMS resonator, and to receive a second reference signal that is generated using the electrostatic MEMS resonator.

The phase-locked loop can be a nested phase-locked loop that includes a first phase-locked loop and a second phase-locked loop. The first phase-locked loop can be configured as a digitally controlled oscillator of the second phase-locked loop. The first phase-locked loop can be configured to receive a first reference signal that is generated using the piezoelectric MEMS resonator. The second phase-locked loop can be configured to receive a second reference signal that is generated using the electrostatic MEMS resonator. The first phase-locked loop can have a higher bandwidth than the second phase-locked loop. The first phase-locked loop and the second phase-locked loop can be fractional-N phase-locked loops. The nested phase-locked loop can include a third phase-locked loop.

The phase-locked loop can be a cascaded phase-locked loop.

The piezoelectric MEMS resonator and the electrostatic MEMS resonator can be on a single die.

The piezoelectric MEMS resonator and the electrostatic MEMS resonator can be on common substrate having a mono-crystalline structure. The piezoelectric MEMS resonator and the electrostatic MEMS resonator are on common silicon carbide substrate. The piezoelectric MEMS resonator and the electrostatic MEMS resonator can be on common silicon-on-insulator substrate.

A resonant frequency of the piezoelectric MEMS resonator can be at least 10 times a resonant frequency of the electrostatic MEMS resonator. The electrostatic MEMS resonator can have a temperature stability that is at least 10 times better than a temperature stability of the piezoelectric MEMS resonator. The electrostatic MEMS resonator can have a temperature stability that is at least 50 times better than a temperature stability of the piezoelectric MEMS resonator. The electrostatic MEMS resonator can have a temperature stability that is in a range from 10 to 50 times better than a temperature stability of the piezoelectric MEMS resonator.

The electrostatic MEMS resonator can be a Lamé mode resonator.

The piezoelectric MEMS resonator can include an aluminum nitride piezoelectric layer.

Another aspect of this disclosure is a timing product that includes a first type of resonator, a second type of resonator on a same die as the first type of resonator, and a phase-locked loop. The first type of resonator provides lower phase noise than the second type of resonator. The second type of resonator has less variation over temperature than the first type of resonator. The phase-locked loop is configured to receive a first reference signal that is generated using the piezoelectric MEMS resonator, and to receive a second reference signal that is generated using the electrostatic MEMS resonator.

The phase-locked loop can be a nested phase-locked loop that includes a first phase-locked loop and a second phase-locked loop. The first phase-locked loop can be configured as a digitally controlled oscillator of the second phase-locked loop. The first phase-locked loop can be configured to receive a first reference signal that is generated using the first type of resonator. The second phase-locked loop can be configured to receive a second reference signal that is generated using the second type of resonator. The first phase-locked loop can have a higher bandwidth than the second phase-locked loop. The first phase-locked loop and the second phase-locked loop can be fractional-N phase-locked loops. The nested phase-locked loop can include a third phase-locked loop.

The phase-locked loop can be a cascaded phase-locked loop.

The first type of resonator and the second type of resonator can be different types of microelectromechanical systems resonators. The first type of resonator can be a piezoelectric microelectromechanical systems (MEMS) resonator, and the second type of resonator can be an electrostatic MEMS resonator.

A resonant frequency of the first type of resonator can be at least 10 times a resonant frequency of the second type of resonator.

The second type of resonator can have a temperature stability that is at least 10 times better than a temperature stability of the first type of resonator. The second type of resonator can have a temperature stability that is at least 50 times better than a temperature stability of the first type of resonator. The second type of resonator can have a temperature stability that is in a range from 10 to 50 times better than a temperature stability of the first type of resonator.

Another aspect of this disclosure is a method of generating a clock signal that includes providing a first reference signal generated using a piezoelectric microelectromechanical systems (MEMS) resonator to a phase-locked loop; providing a second reference signal generated using an electrostatic MEMS resonator to the phase-locked loop; and outputting the clock signal from the phase-locked loop.

The phase-locked loop can be a nested phase-locked loop. The nested phase-locked loop can include a first phase-locked loop configured to receive the first reference signal and a second phase-locked configured to receive the second reference signal.

### BRIEF DESCRIPTION OF THE DRAWINGS

Embodiments of this disclosure will now be described, by way of non-limiting example, with reference to the accompanying drawings.

FIG. 1 is a schematic block diagram of a microelectromechanical systems (MEMS) chip with two types of resonators according to an embodiment.

FIG. 2 is a schematic block diagram of a timing product that that includes a MEMS chip according to an embodiment.

FIG. 3 is a schematic diagram of an oscillator that includes a MEMS resonator according to an embodiment.

FIG. 4 is a schematic diagram of an example piezoelectric MEMS resonator according to an embodiment.

FIG. 5 is a schematic diagram of an example electrostatic MEMS resonator according to an embodiment.

FIG. 6A is a schematic diagram of a nested phase-locked loop (PLL) that receives reference signals that are generated using two types of MEMS resonators according to an embodiment.

FIG. 6B is a schematic diagram of the nested PLL of FIG. 6A that illustrates a first PLL as a digitally controlled oscillator of a second PLL.

FIG. 7 is a schematic diagram a nested PLL that receives reference signals that are generated using two types of MEMS resonators according to an embodiment, where the nested PLL includes more than 2 PLLs.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

This disclosure provides microelectromechanical systems (MEMS) resonator methods, devices, processes, and phase-locked loop (PLL) methods that can address both stability and phase noise specifications of an oscillator reference at the same time. Technology disclosed herein can also address aging and temperature sensitivity in MEMS resonators that provide relatively low equivalent series resistance (ESR) and relatively low phase noise.

Certain technical solutions for oscillator frequency references address either temperature stability or phase noise. For example, using an electrostatic MEMS resonator in an oscillator frequency reference can achieve desirable temperature stability. An electrostatic MEMS resonator can be referred to as a capacitive MEMS resonator. As another example, using a piezoelectric MEMS resonator in an oscillator frequency reference can achieve desirable phase noise performance. In these examples, either (1) temperature stability challenges are addressed at the expense of phase noise challenges or (2) phase noise challenges are addressed at the expense of temperature stability challenges.

Aspects of this disclosure relate to a MEMS chip that includes two types of MEMS resonators on a single chip. The chip can include an electrostatic MEMS resonator and a piezoelectric MEMS resonator. The electrostatic MEMS resonator can provide desirable stability and aging performance. The piezoelectric MEMS resonator can provide desirable phase noise performance. Process steps can be combined to realize the electrostatic MEMS resonator and the piezoelectric MEMS resonator in one process.

The two types of MEMS resonators can be used to generate reference signals for a nested PLL architecture. The electrostatic MEMS resonator can be used to generate a first reference signal for an outer, lower bandwidth PLL of the nested PLL. The piezoelectric MEMS resonator can be used to generate a second reference signal for an inner, higher bandwidth PLL of the nested PLL. Such a nested PLL can generate a highly stable and ultra-low phase noise oscillator frequency reference.

The two types of MEMS resonators can be used to generate reference signals for any other suitable PLL topology. For example, the two types of MEMS resonators can be used to generate reference signals for a cascaded PLL. In this example of a cascaded PLL, the electrostatic MEMS resonator can be used to generate a first reference signal for a first PLL of the and the piezoelectric MEMS resonator can be used to generate a second reference signal for a voltage-controlled oscillator (VCO). As another example, the two types of MEMS resonators can be used to generate reference signals for two PLLs, where one PLL is used to generate a temperature or noise correction signal for the other PLL.

Technical solutions with one type of MEMS resonator in an oscillator solution may only achieve high stability or ultra-low phase noise. Embodiments of this disclosure can achieve both low phase noise and high stability.

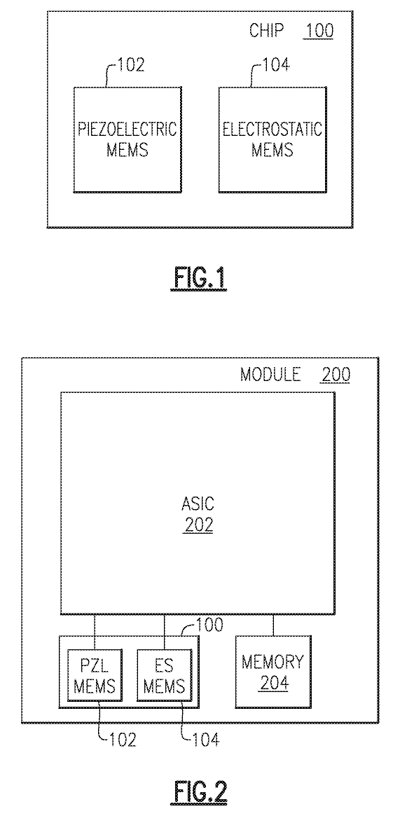

FIG. 1 is a schematic block diagram of a microelectromechanical systems (MEMS) chip 100 with two types of resonators according to an embodiment. As illustrated, the MEMS chip 100 includes a piezoelectric MEMS resonator 102 and an electrostatic MEMS resonator 104. The piezoelectric MEMS resonator 102 and the electrostatic MEMS resonator 104 can be on a common substate. The common substrate can have a mono-crystalline structure. The common substrate can be a semiconductor substrate, such as a silicon substrate, a silicon-on-insulator substrate, a semiconductor-on-insulator substrate, a silicon carbide substate, a 4H-SiC substrate, or the like. Process steps for manufacturing the piezoelectric MEMS resonator 102 and process steps for manufacturing the electrostatic MEMS resonator 104 can be combined to manufacture the MEMS chip 100.

The piezoelectric MEMS resonator 102 can have a higher resonant frequency than the electrostatic MEMS resonator 104. For example, a resonant frequency of the piezoelectric MEMS resonator 102 can be at least 10 times a resonant frequency of the electrostatic MEMS resonator 104. In certain applications, the piezoelectric MEMS resonator 102 can have a resonant frequency in a range from 500 megahertz (MHz) to 3 gigahertz (GHz). In some applications, the electrostatic MEMS resonator can have a resonant frequency in a range from 10 MHz to 200 MHz. The piezoelectric MEMS resonator 102 can achieve better phase noise performance than the electrostatic MEMS resonator 104.

The electrostatic MEMS resonator 104 can have a temperature stability that is higher than the temperature stability of the piezoelectric MEMS resonator 102. For example, the temperature stability of the electrostatic MEMS resonator 104 can be at least 10 times better than the temperature stability of the piezoelectric MEMS resonator 102. In some applications, the temperature stability of the electrostatic MEMS resonator 104 can be in a range from 10 to 50 times better than the temperature stability of the piezoelectric MEMS resonator 102. As another example, the temperature stability of the electrostatic MEMS resonator 104 can be at least 50 times better than the temperature stability of the piezoelectric MEMS resonator 102.

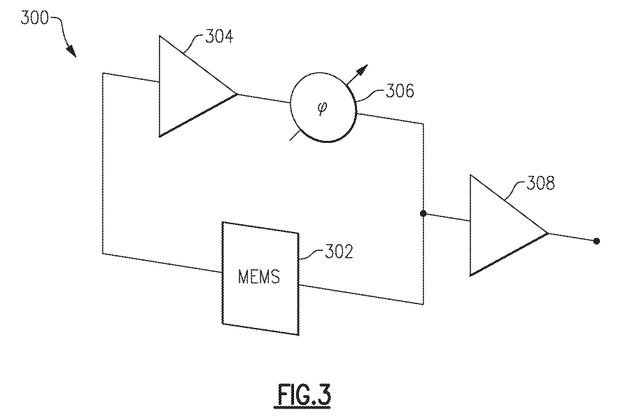

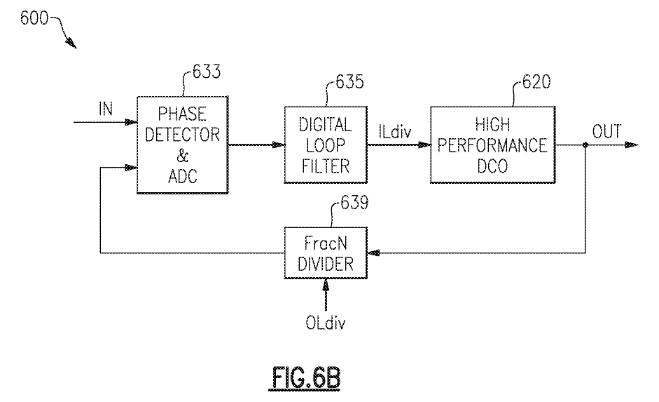

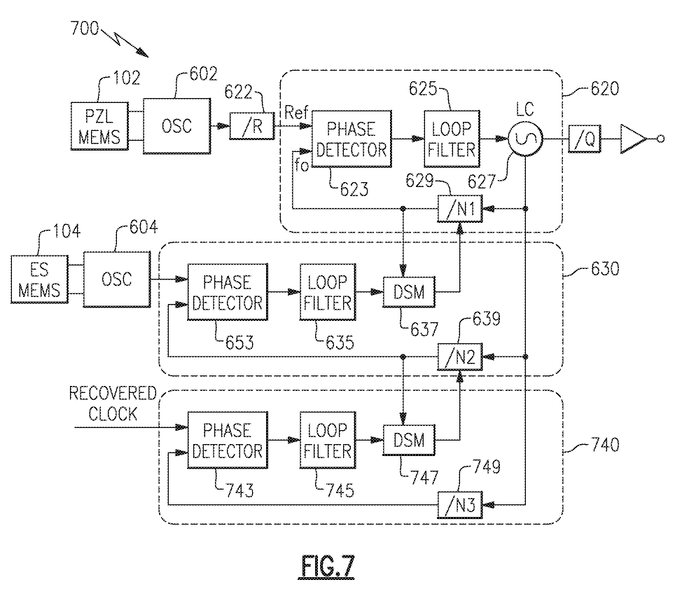

FIG. 2 is a schematic block diagram of a timing product 200 that includes a MEMS chip 100 according to an embodiment. The timing product 200 can provide a clock signal for any suitable system with a need for a clock signal. For example, the timing product 200 can provide a clock signal for a communication system, a network interface card, a vehicular system, an enterprise system, an industrial system, or the like. As illustrated, the timing product 200 can be a packaged module. The timing product 200 includes the MEMS chip 100, an application specific integrated circuit (ASIC) 202, and a memory 204. The ASIC 202 can include a nested PLL, such as the nested PLL of FIGS. 6A-6B or the nested PLL of FIG. 7. The ASIC 202 can include oscillator circuitry that generates reference clock signals using the piezoelectric MEMS resonator 102 and the electrostatic MEMS resonator 104. The MEMS chip 100, the ASIC 202, and the memory 204 can be enclosed by a packaging structure. The MEMS chip 100, the ASIC 202, and the memory 204 can be positioned on a packaging substrate.

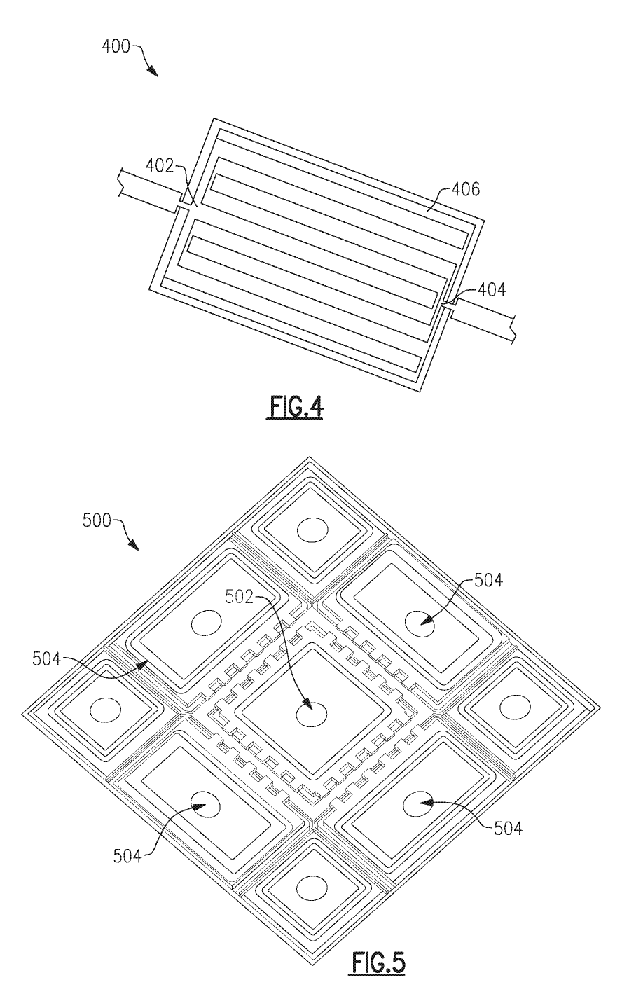

FIG. 3 is a schematic diagram of an oscillator 300 that includes a MEMS resonator 302 according to an embodiment. As illustrated, the oscillator 300 includes the MEMS resonator 302, a MEMS driver 304, a phase shifter 306, and an output driver 308. In the oscillator 300, the MEMS resonator 302 can be a relatively high quality factor (Q) frequency selective device. The oscillator 300 can have a phase noise that is comparable or better than a quartz crystal based oscillator. The MEMS resonator 302 can have a frequency up to a single digit gigahertz (GHz) range, for example. The oscillator 300 can have a loop gain with a magnitude of 1. The loop of the oscillator can have a phase shift of 2nπ.

Oscillator figures of merit can include frequency stability (e.g. temperature variations, aging, etc.) and phase noise. Some other oscillator figures of merit can include one or more of frequency coverage and/or resolution, power consumption, robustness to shock and vibration, cost, or the like. MEMS based oscillators can have comparable or better frequency stability than quartz crystal based oscillators. MEMS based oscillators can operate at higher frequencies than quartz crystal based oscillators. MEMS based oscillators can be programmable and have more features than quartz crystal based oscillators.

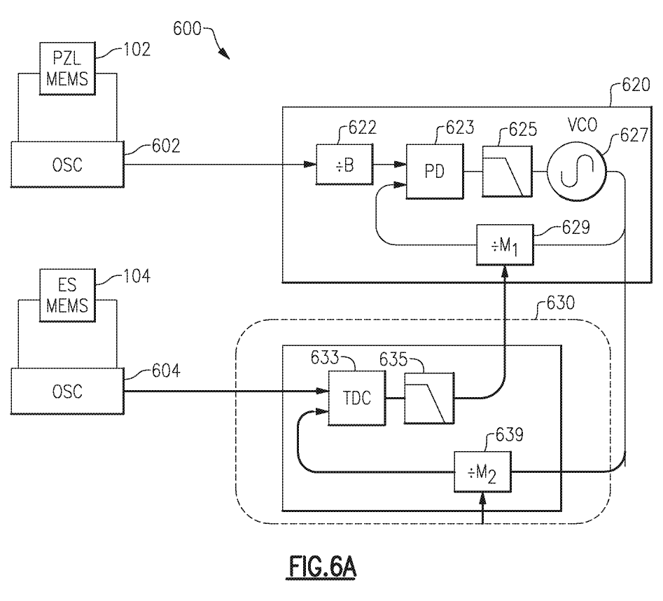

As discussed above, a MEMS chip can include a piezoelectric MEMS resonator 102 and an electrostatic MEMS resonator 104. An example piezoelectric MEMS resonator will be discussed with reference to FIG. 4. An example electrostatic MEMS resonator will be discussed with reference to FIG. 5.

A piezoelectric MEMS resonator can include piezoelectric material positioned between two electrodes. The piezoelectric material can convert electric energy (e.g., from the MEMS driver 304 of FIG. 3) into mechanical energy. The mechanical energy can create vibrations that can produce a stable clock reference signal. A longitudinal piezoelectric effect can generate an acoustic wave. The piezoelectric MEMS resonator 102 of FIG. 1 and 2 can be any suitable piezoelectric MEMS resonator for generating a reference clock signal.

FIG. 4 is a schematic diagram of an example piezoelectric MEMS resonator 400 according to an embodiment. The piezoelectric MEMS resonator 400 includes an input electrode 402 and an output electrode 404. These electrodes can be positioned on a layer of piezoelectric material 406. An electrode can be positioned on the opposite side of the layer of piezoelectric material 406 than the input electrode 402 and the output electrode 404. An electrode and piezoelectric stack of the piezoelectric MEMS resonator 400 can be positioned on a semiconductor substrate, such as a silicon substrate. The layer of piezoelectric material 406 can include any suitable piezoelectric material. The layer of piezoelectric material 406 can be an aluminum nitride layer. The layer of piezoelectric material 406 can be an aluminum nitride layer doped with scandium.

Other example MEMS resonators with a piezoelectric layer include bulk acoustic wave (BAW) resonators, such as a film bulk acoustic wave resonator (FBAR) and a BAW solidly mounted resonator (SMR). Such MEMS resonators can have a resonant frequency in the single digit GHz range. BAW resonators can be voltage tunable. BAW resonators can have metal electrodes. Certain BAW resonators can be formed in metal-less processes, in which silicon and/or polysilicon can be used as at least one BAW resonator electrode.

The electrostatic MEMS resonator 104 of FIG. 1 and 2 can be any suitable electrostatic MEMS resonator for generating a reference clock signal. An electrostatic MEMS resonator can be referred to as a capacitive MEMS resonator.

An electrostatic MEMS resonator can be formed using a high-aspect ratio 3-dimensional silicon process. Such a process can be a high aspect ratio combined poly and single-crystal silicon process. This process can overcome technical challenges of previous high aspect ratio technologies. Scalable air-gap technology can be formed. Nanometer scale airgaps can be formed between 10 micron to 100 micron thick silicon structures. Such electrostatic MEMS devices can have one or more of a relatively high signal to noise ratio, relatively high Q and stability, and a relatively high frequency and desirable immunity to environmental vibrations.

An electrostatic MEMS resonator can be a Lamé mode resonator. For instance, an electrostatic MEMS resonator can be a distributed Lamé mode resonator (DLR). A distributed Lamé mode resonator can achieve a relatively high frequency, be relatively robust to thickness variations (e.g., silicon-on-insulator thickness variations), and have a relatively high temperature turnover point. A Lamé mode resonator can be on a silicon substrate, a silicon-on-insulator substrate, a silicon carbide substrate such as a 4H-SiC substrate, or the like. A 4H-SiC substrate is an example monocrystalline SiC substrate.

FIG. 5 is a schematic diagram of an example electrostatic MEMS resonator 500 according to an embodiment. The electrostatic MEMS resonator 500 is a DLR. As illustrated, the electrostatic MEMS resonator 500 includes a drive electrode 502 and sense electrodes 504. Interfaces of the drive electrode 502 and respective sense electrodes 504 can include interdigitated transduction areas. The electrostatic MEMS resonator 500 can have a frequency in a range from 10s of megahertz (MHz) to several hundred MHz, for example. A DLR can be used in high frequency temperature stable applications. The electrostatic MEMS resonator 500 can be on a silicon substrate, a silicon-on-insulator substrate, a silicon carbide substrate such as a 4H-SiC substrate, or the like. A 4H-SiC substrate is an example monocrystalline SiC substrate.

MEMs chips disclosed herein that include two types of MEMS resonators can be used in a variety of timing products. Some such timing products can include a nested PLL architecture. The nested PLL architecture can include fractional-N PLLs. The nested PLL architecture can include quantization noise cancellation. The nested PLL architecture can include an inner PLL for clock synthesis and an outer PLL for jitter cleaning. The inner PLL can function as a digitally controlled oscillator (DCO) for the outer PLL.

Nested PLLs can be highly integrated. For example, there can be no external oscillator or loop components. Consistent performance can be achieved across process, voltage, and temperature. Clock signals can be generated with flexible frequency with a nested PLL. For example, any frequency synthesis with less than 1 ppt resolution can be generated. Nested PLLs can have adjustable jitter cleaning. The outer PLL can have a digitally programmable loop bandwidth. The tradeoff between jitter generation and jitter transfer can be optimized and/or adjusted as desired.

FIG. 6A is a schematic diagram of a nested PLL 600 that receives reference signals that are generated using two types of MEMS resonators according to an embodiment. A first reference clock signal for the nested PLL 600 can be generated using a first oscillator that includes a piezoelectric MEMS resonator 102 and an oscillator circuit 602. A second reference clock signal for the nested PLL 600 can be generated using a second oscillator that includes an electrostatic MEMS resonator 104 and an oscillator circuit 604. The piezoelectric MEMS resonator 102 can provide desirable phase noise performance. The electrostatic MEMS resonator 104 can provide desirable stability and aging performance. Accordingly, the nested PLL can achieve both (1) desirable phase noise performance and (2) desirable stability and aging performance. The electrostatic MEMS resonator and the piezoelectric MEMS resonator can be on a single chip.

The nested PLL 600 includes a first PLL 620 and a second PLL 630. The first PLL 620 is an inner PLL and the second PLL 630 is an outer PLL in the nested PLL 600. The first PLL 620 is an inner PLL that can function as a DCO for the second PLL 630. As illustrated, the first PLL 620 includes a phase-frequency detector (PFD) 623, a loop filter 625, and a voltage-controlled oscillator (VCO) 627, a feedback divider 629. The first PLL 620 can also include an input divider 622 to divide the first reference clock signal and provide a divided reference clock signal to the PFD 623. The first reference clock signal can be generated using the piezoelectric MEMS resonator 102. The PFD 623 can also receive a feedback signal from the feedback divider 629. The PFD 623 can generate an error signal. The error signal can be provided to the loop filter 625. The loop filter 625 can control the VCO 627 based on the error signal. The VCO 627 can be an LC oscillator, for example.

The input divider 622 can divide the first refence clock signal generated by the first oscillator and provide the divided first reference clock signal provided to the PFD 623. The divided first reference clock can have a frequency in a range from about 400 MHz to 800 MHz. The frequency of the divided first reference clock signal can correspond to an update rate for the first PLL 620. The update rate for the first PLL 620 can determine how often values of the first PLL 620, such as an output signal from the PFD 623 are updated. A higher update rate allows the PLL to be adjusted more frequently than a PLL with a lower update rate.

The second PLL 630 can control the feedback divider 629 of the first PLL 620. As illustrated, the second PLL 630 includes a time to digital converter (TDC) 633, a loop filter 635, and a feedback divider 639. The loop filter 635 and the feedback divider 639 are connected to the first PLL 620. The first PLL 620 functions as a DCO of the second PLL 630.

In the second PLL 630, the TDC 633 is an example of a PFD. The TDC 633 can receive a reference clock signal from the second oscillator and a feedback signal from the feedback divider 639. The TDC 633 can generate an error signal and provide the error signal to the loop filter 635. The error signal can represent a difference between the feedback signal and the second refence clock signal. The second reference clock signal is generated using the electrostatic MEMS resonator 104. In some applications, an input divider (not illustrated in FIG. 6A) can be coupled between the second oscillator and the second PLL 630 to divide the frequency of the second reference clock signal.

The loop filter 635 can generate a control signal based on the error signal from the TDC 633. In some applications, the control signal can be provided to a delta sigma modulator (not illustrated in FIG. 6A). The delta sigma modulator can function as a divider control circuit to control the feedback divider 629 of the first PLL 620. The feedback divider 629 can have a divider value of M1. M1 can be controlled based on an output of the loop filter 635 of the second PLL 630. The output signal from the VCO 627 can be utilized by both the first PLL 620 and the second PLL 630. The feedback divider 639 of the second PLL can receive a feedback signal from the VCO 627 of the first PLL 620. The feedback divider 639 can have a divider value of M2. The divider value of the feedback divider 639 can be programmable.

The second PLL 630 typically has a smaller bandwidth than the first PLL 610. In nested PLLs, the innermost loop can have a widest bandwidth and the outermost loop can have a narrowest bandwidth. PLLs can be implemented using digital architectures due to relatively large time-constants for realizing lower bandwidths can be implemented as weights in the digital domain whereas such narrow bandwidth PLLs would typically involve large chip area to implement the loop filter capacitor in the analog domain. The use of the TDC 633 in the nested PLL 600 can realize advantages of a digital implementation for the second PLL 630.

The loop bandwidth of the first PLL 620 can be in a range between 1 MHz to 10 MHz. The loop bandwidth of the second PLL 630 can be in a range from 10 kilohertz (kHz) to 500 kHz. The loop bandwidth of the inner loop can be least an order of magnitude greater than the loop bandwidth of the outer loop.

Although the nested PLL 600 of FIG. 6A includes a first PLL 620 that receives a reference clock signal generated using a piezoelectric MEMS resonator 102 and a second PLL 630 that receives a reference clock signal generated using an electrostatic MEMS resonator 104, reference clock signals generated using a piezoelectric MEMS resonator and an electrostatic MEMS resonator can be provided to any suitable PLLs in a nested PLL. For example, in certain applications (not illustrated in FIG. 6A), a first PLL can receive a reference clock signal generated using an electrostatic MEMS resonator and a second PLL can receive a reference clock signal generated using a piezoelectric MEMS resonator, in which the first PLL functions as a DCO for the second PLL.

FIG. 6B is a schematic diagram of the nested PLL 600 of FIG. 6A that illustrates a first PLL 620 as a DCO of a second PLL 630. FIG. 6B illustrates that the first PLL 620 can function as a DCO. In FIG. 6B, the feedback divider 639 can receive an outer loop divider signal OLdiv. The first PLL 620 can receive an inner looper divider signal ILdiv.

In certain applications, the nested PLL 600 can be a voltage-controlled oscillator. An analog-to-digital converter can receive a voltage control signal and convert the voltage control signal to a digital control signal. The digital control signal can be provided to a delta sigma modulator. The delta sigma modulator can generate a divider control signal for the feedback divider 639. Accordingly, the voltage control signal can control a divider ratio of the feedback divider 639, which can in turn control the output clock signal provided by the nested PLL 600.

FIG. 7 is a schematic diagram a nested PLL 700 that receives reference signals that are generated using two types of MEMS resonators according to an embodiment, where the nested PLL includes more than 2 PLLs. Although the nested PLL 600 includes two PLLs, other nested PLLs can include three or more PLLs. The nested PLL 700 includes 3 PLLs. The nested PLL 700 can be referred to as a nested triple loop PLL, and the nested PLL 600 of FIGS. 6A and 6B can be referred to as a nested dual loop PLL.

The nested PLL 700 includes a first PLL 620, a second PLL 630, and a third PLL 740. The first PLL 620 and the second PLL 630 can be implemented in accordance with any suitable principles and advantages discussed with reference to FIGS. 6A and 6B. In FIG. 7, the TDC 633 of FIG. 6A is illustrated as a PFD 653. FIG. 7 also illustrates a delta sigma modulator 637, which can function as discussed above. The VCO 627 of the first PLL 620 is illustrated as an LC oscillator in FIG. 7.

The third PLL 740 can receive a recovered clock signal. A clock and data recovery (CDR) circuit (not shown in FIG. 7) can recover the clock signal from data received by the CDR circuit and supply the recovered clock signal to the third PLL 740. The third PLL 740 can include a PFD 743, a loop filter 745, a delta sigma modulator 747, and a feedback divider 749. The PFD 743 can receive the recovered clock signal, compare the recovered clock signal to a feedback signal from the feedback divider 749, and provide an error signal indicative of the comparison to the loop filter 745. The loop filter 745 can filter the error signal and provide a loop filter output to the delta sigma modulator 747. The delta sigma modulator 747 can control the feedback divider 639 of the second PLL 630. The feedback divider 639 is in a middle loop of the nested PLL 700. The nested PLL 700 can lock the output clock signal provided by the VCO 627 to the recovered clock signal.

The recovered clock signal can be a relatively noisy signal. Accordingly, the bandwidth of the third PLL 740 can be relatively narrow to filter out the noise. For example, the bandwidth of the third PLL 740 can be at least an order of magnitude lower than the bandwidth of second PLL 630. In certain applications the bandwidth of the third PLL 740 is less than a few kilohertz (kHz), e.g., in the tens or hundreds of Hertz (Hz).

Nested PLL architectures are disclosed that can be advantageously used for various timing products. While embodiments may have two or three loops, a nested PLL in accordance with any suitable principles and advantages disclosed herein can have more than three loops. In addition, while the third PLL 740 of FIG. 7 has a recovered clock as an input, other embodiments may have other types of clock signals as the reference clock signal for the third loop and/or for one or more additional loops.

Although embodiments may be discussed with reference to a piezoelectric MEMS resonator and an electrostatic MEMS resonator, any suitable principles and advantages disclosed herein can be applied to a nested PLL that receives clock signals generated using a first type of resonator and a second type of resonator on a same die as the first type of resonator, where the first type of resonator provides lower phase noise than the second type of resonator, and where the second type of resonator has less variation over temperature than the first type of resonator.

Aspects of this disclosure can be implemented in various electronic devices. Examples of the electronic devices can include, but are not limited to, communications products, timing products, consumer electronic products, uplink wireless communication devices, wireless communication infrastructure, electronic test equipment, parts of any of these products, devices, equipment, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks, elements, layers, or other structures are presented in a given arrangement, alternative embodiments may perform similar functionalities with different components and/or circuit topologies, and some blocks may be deleted, moved, added, subdivided, combined, and/or modified. Each of these blocks, elements, layers, or other structures may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A timing product comprising:
a microelectromechanical systems (MEMS) resonator chip including a substrate, a piezoelectric MEMS resonator on the substrate, and an electrostatic MEMS resonator on the substrate; and
a phase-locked loop configured to receive a first reference signal that is generated using the piezoelectric MEMS resonator, and to receive a second reference signal that is generated using the electrostatic MEMS resonator.

2. The timing product of claim 1 wherein the phase-locked loop is a nested phase-locked loop including a first phase-locked loop and a second phase-locked loop, the first phase-locked loop configured as a digitally controlled oscillator of the second phase-locked loop, the first phase-locked loop configured to receive the first reference signal, and the second phase-locked loop configured to receive the second reference signal.

3. The timing product of claim 2 wherein the nested phase-locked loop includes a third phase-locked loop.

4. The timing product of claim 2 wherein the first phase-locked loop has a higher bandwidth than the second phase-locked loop.

5. The timing product of claim 1 wherein the phase-locked loop is a cascaded phase-locked loop.

6. The timing product of claim 1 wherein the substrate has a mono-crystalline structure.

7. The timing product of claim 1 wherein the substrate is a silicon carbide substrate.

8. The timing product of claim 1 wherein substrate is a silicon-on-insulator substrate.

9. The timing product of claim 1 wherein a resonant frequency of the piezoelectric MEMS resonator is at least 10 times a resonant frequency of the electrostatic MEMS resonator.

10. The timing product of claim 1 wherein the electrostatic MEMS resonator has a temperature stability that is at least 10 times better than a temperature stability of the piezoelectric MEMS resonator.

11. The timing product of claim 1 wherein the electrostatic MEMS resonator is a Lamé mode resonator.

12. The timing product of claim 1 wherein the electrostatic MEMS resonator is a distributed Lamé mode resonator.

13. The timing product of claim 1 further comprising a memory and a packaging structure, the phase-locked loop being included on an application specific integrated circuit, and the packaging structure enclosing the application specific integrated circuit and the memory and the MEMS resonator chip.

14. A timing product comprising:
a first type of resonator;
a second type of resonator on a same die as the first type of resonator, the first type of resonator providing lower phase noise than the second type of resonator, and the second type of resonator having less variation over temperature than the first type of resonator; and
a phase-locked loop configured to receive a first reference signal that is generated using the first type of resonator, and to receive a second reference signal that is generated using the second type of resonator.

15. The timing product of claim 14 wherein the phase-locked loop is a nested phase-locked loop including a first phase-locked loop and a second phase-locked loop, the first phase-locked loop configured as a digitally controlled oscillator of the second phase-locked loop, the first phase-locked loop configured to receive the first reference signal, and the second phase-locked loop configured to receive the second reference signal.

16. The timing product of claim 14 wherein the first type of resonator and the second type of resonator are different types of microelectromechanical systems resonators.

17. The timing product of claim 14 wherein the first type of resonator is a piezoelectric microelectromechanical systems (MEMS) resonator, and the second type of resonator is an electrostatic MEMS resonator.

18. The timing product of claim 14 wherein a resonant frequency of the first type of resonator is at least 10 times a resonant frequency of the second type of resonator.

19. The timing product of claim 14 wherein the second type of resonator has a temperature stability that is at least 10 times better than a temperature stability of the first type of resonator.

20. A method of generating a clock signal, the method comprising:
providing a first reference signal generated using a piezoelectric microelectromechanical systems (MEMS) resonator to a phase-locked loop;
providing a second reference signal generated using an electrostatic MEMS resonator to the phase-locked loop, the electrostatic MEMS resonator and the piezoelectric MEMS resonator being included on a single chip; and
outputting the clock signal from the phase-locked loop.
